(19) United States
(12) Patent Application Publication
(10) Pub. No.: US 2024/0096603 A1
(43) Pub. Date: Mar. 21, 2024

(54) APPARATUS FOR TREATING SUBSTRATE

(71) Applicant: SEMES CO., LTD., Cheonan-si (KR)

(72) Inventors: Dong-Hun KIM, Gunpo-si (KR); Wan Jae PARK, Hwaseong-si (KR); Dong Sub OH, Busan (KR); Myoung Sub NOH, Hwaseong-si (KR); Ji Hoon PARK, Hwaseong-si (KR)

(73) Assignee: SEMES CO., LTD., Cheonan-si (KR)

(21) Appl. No.: 18/469,755

(22) Filed: Sep. 19, 2023

(30) Foreign Application Priority Data
Sep. 20, 2022 (KR) 10-2022-0118542

(51) Int. Cl. H01J 37/32

(52) U.S. Cl. CPC H01J 37/3244; H01J 37/32422; H01J 2237/334; H01L 21/67069

(57) ABSTRACT

The inventive concept provides a substrate treating apparatus. The substrate treating apparatus includes an electrode plate applied with a power; an ion blocker positioned at a bottom side of the electrode plate, which has a plurality of top holes formed thereon, and which is grounded; a shower head positioned at a bottom side of the ion blocker and which has a plurality of bottom holes formed thereon; and a turbulence generating unit configured to have a turbulence space therein, and which is positioned at a space between the ion blocker and the shower head, and wherein the top hole is positioned to overlap the turbulence space when seen from above, and the bottom hole is positioned at an outer side of the turbulence space, and which faces at least one of a bottom surface of the ion blocker and an outer wall of the turbulence generating unit when seen from below.

### CROSS-REFERENCE TO RELATED APPLICATIONS

A claim for priority under 35 U.S.C. § 119 is made to Korean Patent Application No. 10-2022-0118542 filed on Sep. 20, 2022, in the Korean Intellectual Property Office, the entire contents of which are hereby incorporated by reference.

### BACKGROUND

Embodiments of the inventive concept described herein relate to a substrate treating apparatus, more specifically, a substrate treating apparatus for plasma treating a substrate.

A plasma refers to an ionized gas state composed of ions, radicals, and electrons. The plasma is generated by very high temperatures, strong electric fields, or RF electromagnetic fields. A semiconductor element manufacturing process may include an etching process of removing a thin film or a foreign substance formed on a substrate such as a wafer using the plasma. The etching process is performed by colliding ions and/or radicals of the plasma with the thin film on the substrate or reacting with the thin film on the substrate.

In general, various thin films including a natural oxide film are stacked on the substrate. In each of the various processes of treating the substrate using the plasma, a suitable selection ratio is required. The selection ratio is determined according to an etching degree of the thin films formed on the substrate. Some of the thin films formed on the substrate may be etched by an etchant formed by reacting a radical with a reaction gas. In addition, some of the other thin films formed on the substrate may be etched by the radical. That is, a target etched by the etchant and a target etched by the radical are different. Accordingly, it is important to adjust a ratio of the etchant and the radical acting on the substrate in order to adjust the selection ratio suitable for the substrate.

### SUMMARY

Embodiments of the inventive concept provide a substrate treating apparatus for efficiently treating a substrate.

Embodiments of the inventive concept provide a substrate treating apparatus for efficiently adjusting a selection ratio.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes an electrode plate applied with a power; an ion blocker positioned at a bottom side of the electrode plate, which has a plurality of top holes formed thereon, and which is grounded; a shower head positioned at a bottom side of the ion blocker and which has a plurality of bottom holes formed thereon; and a turbulence generating unit configured to have a turbulence space therein, and which is positioned at a space between the ion blocker and the shower head, and wherein the top hole is positioned to overlap the turbulence space when seen from above, and the bottom hole is positioned at an outer side of the turbulence space, and which faces at least one of a bottom surface of the ion blocker and an outer wall of the turbulence generating unit when seen from below.

In an embodiment, the turbulence generating unit is configured to be formed at a top end of the shower head and which has an open top portion, and a top end of the turbulence generating unit is positioned apart from a bottom end of the ion blocker.

In an embodiment, the turbulence generating unit has a shape of which a diameter decreases in a direction toward the shower head.

In an embodiment, the turbulence generating unit has a cylinder shape.

In an embodiment, the top hole and the bottom hole are positioned to not overlap each other when seen from above.

In an embodiment, the turbulence generating unit includes: a first turbulence generating unit formed at a top end of the shower head and which is configured to have a first turbulence space therein, and which has an open top portion; and a second turbulence generating unit formed at a bottom end of the ion blocker and which is configured to have a second turbulence space therein, and which has an open bottom portion, and wherein the top hole is positioned to overlap the first turbulence space when seen from above, and the bottom hole is positioned to overlap the second turbulence space when seen from above.

The inventive concept provides a substrate treating apparatus having a first space, a second space which is below the first space, and a third space which is below the second space and which treats a substrate. The substrate treating apparatus includes a first gas line which supplies a first gas to the first space; a second gas line which supplies a second gas to the second space; a first plate and a second plate which couple to define the second space; and a turbulence generating unit configured to have a turbulence space therein, and which is positioned in the second space and which generates a turbulence in the turbulence space and second space, and wherein a plurality of first holes are formed at the first plate which communicate with the first space and the second space, and the first hole is positioned to overlap with the turbulence space when seen from above.

In an embodiment, the first plate is positioned above the second plate, and wherein the turbulence generating unit has an open top portion, and which is formed at a top end of the second plate.

In an embodiment, the second plate has a plurality of second holes which communicate with the second space and the third space, and wherein the plurality of second holes are positioned at an outside of the turbulence space.

In an embodiment, a plurality of second gas discharge ports connected to the second gas line are formed at a top portion of the second plate, and the second gas discharge ports are positioned at the outside of the turbulence space.

In an embodiment, the first hole, the second hole, and the second gas discharge port are disposed to not overlap each other when seen from above.

In an embodiment, a top end of the turbulence generating unit is spaced apart from the bottom end of the first plate.

In an embodiment, the turbulence generating unit has a shape of which a diameter decreases from the top end to a bottom end, and the plurality of second holes overlap with at least a portion of an outer wall of the turbulence generating unit when seen from below.

In an embodiment, the turbulence generating unit has a cylinder shape, and the plurality of second holes face the bottom surface of the first plate when seen from below.

In an embodiment, the substrate treating apparatus further includes: an electrode plate which is spaced apart from the first plate and positioned at a top side of the first plate, and wherein the electrode plate is applied with a high frequency power, and the first plate is grounded.

In an embodiment, a plurality of first gas discharge ports connected to the first gas line are formed at a bottom portion of the first plate, and the plurality of first gas discharge ports are positioned to not overlap each of the plurality of first holes when seen from above.

In an embodiment, the first space generates a plasma by exciting the first gas, and the second gas forms an etchant by reacting a radical among a material including the plasma and the second gas.

In an embodiment, the first gas includes an NF₃, and the second gas includes an NH₃.

In an embodiment, the substrate treating apparatus further includes a pre gas line supplying a pre-gas to the first space, and wherein the pre-gas reacts with the radical in the first space.

The inventive concept provides a substrate treating apparatus. The substrate treating apparatus includes an electrode plate applied with a high frequency power; an ion blocker positioned at a bottom side of the electrode plate and spaced apart from the electrode plate, which has a plurality of top holes formed thereon, and which is grounded; a shower head positioned at a bottom side of the ion blocker and spaced apart from the ion blocker, and which has a plurality of bottom holes formed thereon; and a turbulence generating unit configured to have a turbulence space therein, and which is positioned at a top end of the shower head; a support unit configured to support a substrate at a bottom side of the shower head; a first gas supply unit configured to supply a first gas to a space between the electrode plate and the ion blocker; and a second gas supply unit configured to supply a second gas to a space between the ion blocker and the shower head, and wherein a top end of the turbulence generating unit is spaced apart from a bottom end of the shower head, the top hole and the bottom hole are positioned to not overlap each other when seen from above, the top hole faces the turbulence space when seen from above, and the bottom hole is positioned at an outside of the turbulence space.

According to an embodiment of the inventive concept, a substrate may be efficiently treated.

According to an embodiment of the inventive concept, an amount of a radical among a radical and an etchant applied to a substrate may be adjusted.

According to an embodiment of the inventive concept, by adjusting an amount of a radical, a required selection ratio according to a recipe may be efficiently adjusted.

The effects of the inventive concept are not limited to the above-described effects, and the effects not mentioned will be clearly understood by those having ordinary skill in the art from the present specification and the accompanying figures.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a perspective view of a turbulence generating unit according to an embodiment.

FIG. 3 schematically illustrates a shower head seen from above according to an embodiment.

FIG. 4 is a cutting perspective view of the shower head and an ion blocker according to an embodiment.

FIG. 5 schematically illustrates a state in which the substrate treating apparatus treats a substrate according to an embodiment.

FIG. 6 schematically illustrates an enlarged view of part A of FIG. 5.

FIG. 7 is a cross-sectional view schematically illustrating the turbulence generating unit according to another embodiment.

FIG. 8 is a perspective view of the turbulence generating unit according to another embodiment of FIG. 7.

FIG. 9 is a cross-sectional view schematically illustrating the turbulence generating unit according to another embodiment.

FIG. 10 is a cross-sectional view schematically illustrating the substrate treating apparatus according to another embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

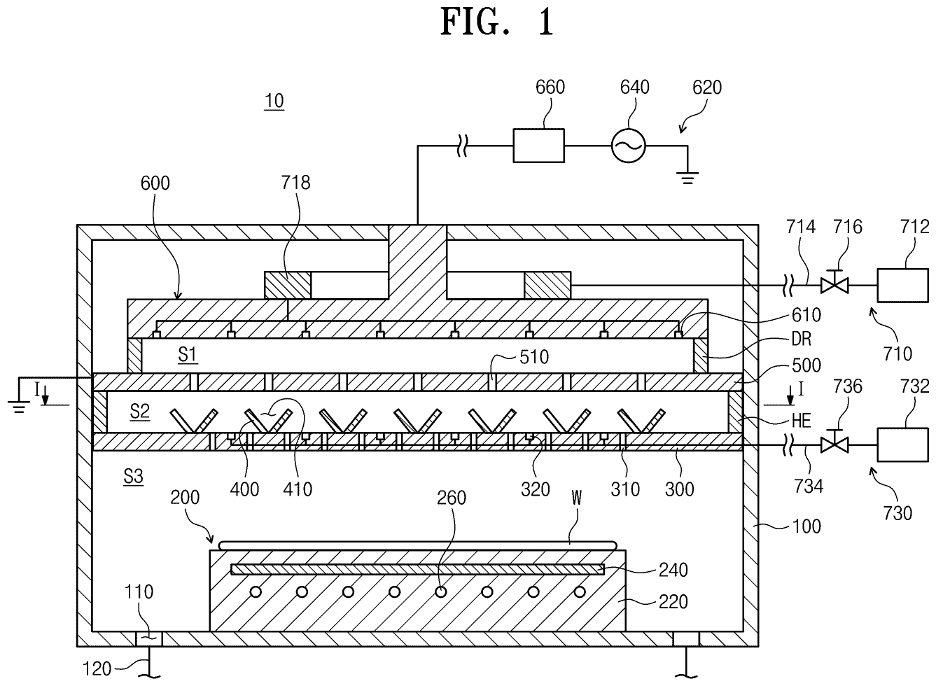

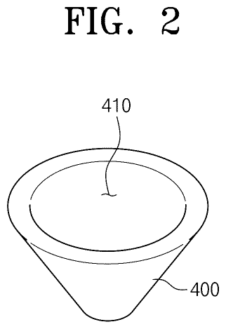

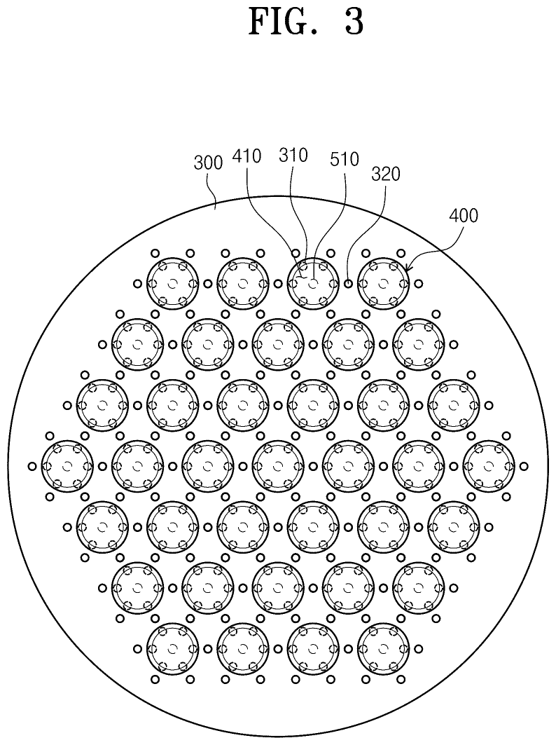

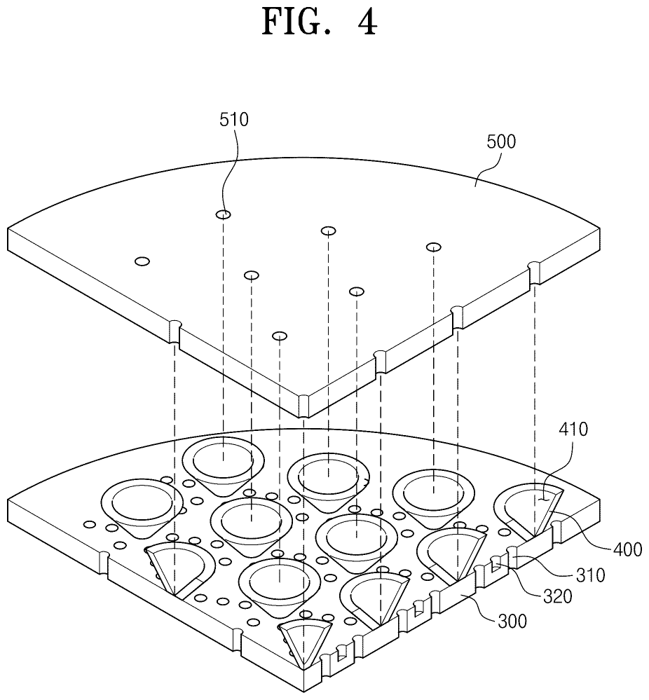

FIG. 1 is a cross-sectional view schematically illustrating a substrate treating apparatus according to an embodiment. FIG. 2 is a perspective view of a turbulence generating unit according to an embodiment. FIG. 3 schematically illustrates a shower head seen from above according to an embodiment. FIG. 4 is a cutting perspective view of the shower head and an ion blocker according to an embodiment.

Referring to FIGS. 1 to 4, the substrate treating apparatus 10 according to an embodiment treats the substrate W. The substrate treating apparatus 10 may treat the substrate W using a plasma. For example, the substrate treating apparatus 10 may perform an etching process to remove a thin film formed on the substrate W using the plasma, an ashing process to remove a photoresist film, a deposition process to form a thin film on the substrate W, or a dry cleaning process. However, the inventive concept is not limited to the above-described example, and the substrate treating apparatus 10 according to an embodiment may be equally or similarly applied to various devices for treating the substrate W using the plasma.

The substrate treating apparatus 10 may include a housing 100, a support unit 200, a shower head 300, a turbulence generating unit 400, an ion blocker 500, an electrode plate 600, and gas supply units 710 and 730.

The housing 100 may have a substantially cylindrical shape. The housing 100 has an inner space. The inner space of the housing 100 is divided into a first space S1, a second space S2, and a third space S3. The first space S1 is defined as a space formed by a combination of the ion blocker 500, the electrode plate 600, and an insulation unit DR to be described later. The second space S2 is defined as a space formed by a combination of the shower head 300, the ion blocker 500, and a heating unit HE to be described later. The third space S3 is defined as a space formed by a combination of the housing 100 and the shower head 300. According to an embodiment, the third space S3 may be a space in which the substrate W is treated. A detailed description of the first space S1 and the second space S2 will be described later.

An inner wall of the housing 100 may be coated with a material capable of preventing an etching by the plasma. For example, the inner wall of the housing 100 may be coated with a dielectric film such as a ceramic. In addition, the housing 100 may be grounded.

An exhaust hole 110 is formed at a bottom of the housing 100. The exhaust hole 110 is connected to the exhaust line 120. A pump (not shown) may be installed in the exhaust line 120. The pump (not shown) applies a negative pressure to the exhaust line 120 to exhaust an atmosphere of the third space S3 to adjust a pressure of the third space S3. In addition, the pump (not shown) discharges foreign substances remaining in the third space S3. In addition, an opening (not shown) through which the substrate W is taken in and out is formed on a sidewall of the housing 100. The opening (not shown) may be selectively opened and closed by a door assembly which is not shown.

The support unit 200 is positioned within the third space S3. The support unit 200 is positioned below the shower head 300 to be described later. The support unit 200 supports the substrate W. The support unit 200 according to an embodiment may be an ESC capable of chucking the substrate W using an electrostatic force.

The support unit 200 may include a body 220, an electrode 240, and a heater 260. The body 220 supports the substrate W. The substrate W is seated on a top surface of the body 220. The body 220 may generally have a disk shape. The body 220 according to an embodiment may be formed of a dielectric substance. An electrode 240 and a heater 260 are disposed within the body 220.

The electrode 240 is disposed at a position overlapping the substrate W when seen from above. The electrode 240 is disposed above the heater 260. The electrode 240 is connected to a DC power source, which is not shown. If the DC power source (not shown) is turned on, a DC current flows through the electrode 240. If the DC current flows through the electrode 240, an electric field is formed by the electrostatic force between the electrode 240 and the substrate W. By the formed electric field, the substrate W is sucked to the body 220.

The heater 260 adjusts a temperature of the substrate W. The heater 260 may heat the body 220. The heater 260 may heat the body 220 to increase the temperature of the substrate W supported on the top surface of the body 220. The substrate W may be maintained at a temperature required for a process by a heat generated by the heater 260. In addition, the heater 260 may increase the temperature of the body 220 to prevent foreign substances (e.g., an oxide film or a nitride film) separated from the substrate W from being reattached to the substrate W while the substrate W is being treated. The heater 260 may be a heating element such as a tungsten. However, a type of the heater 260 is not limited thereto, and may be variously modified and provided with a known heating element. In addition, unlike the above-described example, the heater 260 may not be disposed within the body 220.

In addition, although not shown, a cooling fluid channel (not shown) through which a cooling fluid flows may be formed within the body 220. The cooling fluid flows along the cooling fluid channel (not shown), and the temperature of the body 220 and the substrate W may be adjusted.

The shower head 300 is disposed above the support unit 200. More specifically, the shower head 300 is disposed to face the substrate W supported by the support unit 200. In addition, the shower head 300 is disposed below the ion blocker 500 to be described later. As described above, the shower head 300 is combined with the housing 100 to define the third space S3. In addition, the shower head 300 is combined with the ion blocker 500 and the heating unit HE to define the second space S2.

The shower head 300 may have a disk shape. The shower head 300 according to an embodiment may be referred to as a second plate. A plurality of bottom holes 310 are formed in the shower head 300. A bottom hole 310 may be referred to as a second hole. The bottom hole 310 according to an embodiment may be a hole penetrating the top surface and the bottom surface of the shower head 300. The second space S2 and the third space S3 may be in fluid communication with each other through the bottom hole 310. The bottom hole 310 is positioned outside the turbulence generating unit 400 to be described later. More specifically, the bottom hole 310 is positioned outside the turbulence space 410 to be described later. According to an embodiment, the bottom hole 310 may face an outer wall of the turbulence generating unit 400 when viewed from below.

Unlike the above-described example, the bottom hole 310 may face a part of the outer wall of the turbulence generating unit 400 when viewed from below. That is, when viewed from below, at least a portion of the bottom hole 310 may face a bottom surface of the ion blocker 500, and the other portion of the bottom hole 310 may face the outer wall of the turbulence generating unit 400.

A second gas discharge port 320 is formed at a top portion of the shower head 300. The second gas discharge port 320 may be configured to be in fluid communication with the second space S2, but not to be in fluid communication with the third space S3. A plurality of second gas discharge ports 320 may be provided. The second gas discharge port 320 is positioned outside the turbulence generation unit 400 to be described later. More specifically, the second gas discharge port 320 is positioned outside the turbulence space 410 to be described later. The second gas discharge port 320 faces the bottom surface of the ion blocker 500 when viewed from below. The second gas discharge port 320 is disposed not to overlap the bottom hole 310. The second gas discharge port 320 may be disposed between the bottom holes 310. The second gas discharge port 320 is connected to a second gas line 734 to be described later.

The turbulence generating unit 400 is positioned in a space between the shower head 300 and the ion blocker 500. That is, the turbulence generating unit 400 is positioned in the second space S2. The turbulence generating unit 400 is formed on a top end of the shower head 300. The turbulence generating unit 400 may have a shape in which a top portion is opened. According to an embodiment, the turbulence generating unit 400 may have a shape of a funnel with an open top. The turbulence generating unit 400 may have a shape in which a diameter decreases from a top end to a bottom end thereof. That is, the turbulence generating unit 400 may have a shape in which the diameter thereof decreases in a direction toward the shower head 300.

In addition, the top end of the turbulence generating unit 400 is positioned to be spaced apart from a bottom end of the ion blocker 500 to be described later. More specifically, when viewed from a front, the top end of the turbulence generating unit 400 is positioned at a height lower than the bottom end of the ion blocker 500. In addition, a plurality of turbulence generating units 400 may be provided. The plurality of turbulence generating units 400 may be disposed to be spaced apart from each other along a circumferential direction of the shower head 300.

The turbulence generating unit 400 has a turbulence space 410 therein. The turbulence generating unit 400 generates a turbulence in the second space S2. In addition, the turbulence generating unit 400 generates the turbulence in the turbulence space 410. A detailed mechanism by which the turbulence generating unit 400 generates the turbulence in the second space S2 and the turbulence space 410 will be described later.

The heating unit HE is positioned above the shower head 300. More specifically, the heating unit HE is positioned between the shower head 300 and the ion blocker 500 to be described later. According to an embodiment, the heating unit HE may be a heater having a ring shape. The heating unit HE may be disposed along a circumference of an edge region of the shower head 300. The heating unit HE may increase a temperature of the second space S2. The heating unit HE may increase the temperature of the second space S2 to increase a mixing efficiency of a plasma from which ions are removed and a second gas to be described later.

The ion blocker 500 may be referred to as a first plate. The ion blocker 500 is disposed above the shower head 300. More specifically, the ion blocker 500 is disposed above the shower head 300 to be spaced apart from the shower head 300. In addition, the ion blocker 500 is disposed below the electrode plate 600 to be described later. In addition, the ion blocker 500 is disposed above the heating unit HE. The heating unit HE is positioned below the edge region of the ion blocker 500. Accordingly, as described above, the second space S2 is defined by a combination of the shower head 300, the ion blocker 500, and the heating unit HE.

The ion blocker 500 is grounded. The ion blocker 500 functions as an opposite electrode the electrode plate 600 to be described later. Accordingly, the ion blocker 500 functions as a plasma source forming the plasma together with the electrode plate 600.

A plurality of top holes 510 are formed in the ion blocker 500. A top hole 510 may be referred to as a first hole. The top hole 510 may be a hole penetrating the top surface and the bottom surface of the ion blocker 500. Accordingly, the first space S1 and the second space S2 may be in fluid communication with each other through the top hole 510.

The top hole 510 may not overlap the bottom hole 310 when seen from above. In addition, the top hole 510 may not overlap the second gas discharge port 320 when seen from above. That is, the top hole 510 may be disposed to deviate from the bottom hole 310 and the second gas discharge port 320. In addition, the top hole 510 is positioned to overlap the turbulence space 410. That is, the top hole 510 is positioned to face the turbulence space 410.

The electrode plate 600 may be generally formed in a disk shape. More specifically, the electrode plate 600 may have a disk shape in which a center thereof upwardly protrudes. The electrode plate 600 is disposed above the ion blocker 500 to be spaced apart from the ion blocker 500. The electrode plate 600 is disposed to face the ion blocker 500. An insulation unit DR made of an insulating material may be disposed between the electrode plate 600 and the ion blocker 500. The insulation unit DR may have a substantially ring shape. The insulation unit DR may electrically insulate the ion blocker 500 from the electrode plate 600. As described above, the ion blocker 500, the electrode plate 600, and the insulation unit DR are combined to define the first space S1.

A power module 620 is electrically connected to the electrode plate 600. The power module 620 applies a power to the electrode plate 600. More specifically, the power module 620 applies a high frequency power to the electrode plate 600. The power module 620 may include a power source 640, an impedance matcher 660, and a power switch which is not shown. The power source 640 may be an RF source. The power source 640 applies the high frequency power to the electrode plate 600. The impedance matcher 660 and the power switch (not shown) are installed between the power source 640 and the electrode plate 600. The impedance matcher 660 matches an impedance of the high frequency power which is applied to the electrode plate 600. If the power switch (not shown) is turned on and the high-frequency power is applied to the electrode plate 600, an electric field is formed between the ion blocker 500 functioning as an opposite electrode and the electrode plate 600. That is, the electric field is formed in the first space S1. The electric field formed in the first space S1 may excite a gas supplied to the first space S1.

A plurality of first gas discharge ports 610 are formed at a bottom part of the electrode plate 600. The first gas discharge port 610 is connected to a first gas line 714 to be described later. The first gas discharge port 610 may be disposed to deviate from the top hole 510 when seen from above.

The gas supply units 710 and 730 supply a gas. The gas supply units 710 and 730 include a first gas supply unit 710 and a second gas supply unit 730.

The first gas supply unit 710 supplies the first gas to the first space S1. The first gas according to an embodiment may be a gas that is excited as a plasma. In addition, the first gas may be referred to as a process gas. For example, the first gas may include an NF₃. In addition, the first gas may include a carrier gas which contributes to a plasma ignition. For example, the first gas may further include an inert gas such as an He or an Ar.

The first gas supply unit 710 may include a first gas source 712, a first gas line 714, and a first valve 716. The first gas source 712 stores the first gas. An end of the first gas line 714 is connected to the first gas source 712. A first valve 716 is installed in the first gas line 714. The first valve 716 may be an on-off valve and/or a flow control valve. In addition, the other end of the first gas line 714 may be connected to a feeding unit 718. The feeding unit 718 may have a substantially ring shape. The feeding unit 718 may be disposed on a top end of the electrode plate 600. The first gas line 714 may be connected to the first gas discharge ports 610 formed under the electrode plate 600 through a feeding unit 718. Accordingly, the first gas is supplied to the first space S1 through the first gas line 714 and the first gas discharge port 610.

The second gas supply unit 730 supplies the second gas to the second space S2. The second gas according to an embodiment may be a gas which reacts with radicals among ions and radicals included in the plasma to form an etchant. Accordingly, the second gas may be referred to as a reaction gas. For example, the second gas may include an NH₃.

The second gas supply unit 730 may include a second gas source 732, a second gas line 734, and a second valve 736. The second gas source 732 stores the second gas. An end of the second gas line 734 is connected to the second gas source 732, and the other end thereof is connected to the second gas discharge port 320. The second valve 736 is installed in the second gas line 734. The second valve 736 may be an on-off valve and/or a flow control valve. The second gas is supplied to the second space S2 through the second gas line 734 and the second gas discharge port 320.

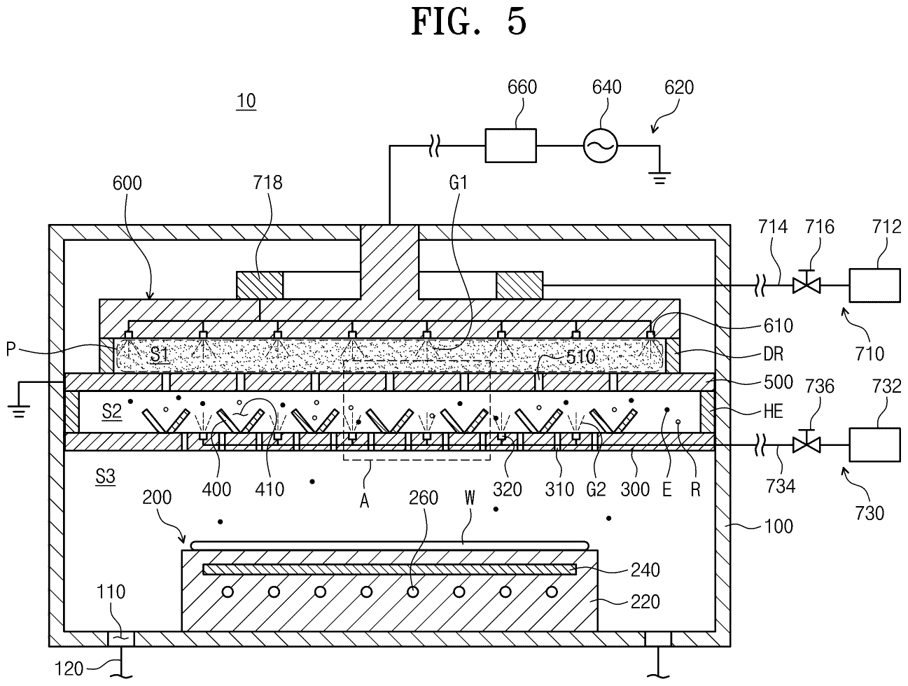

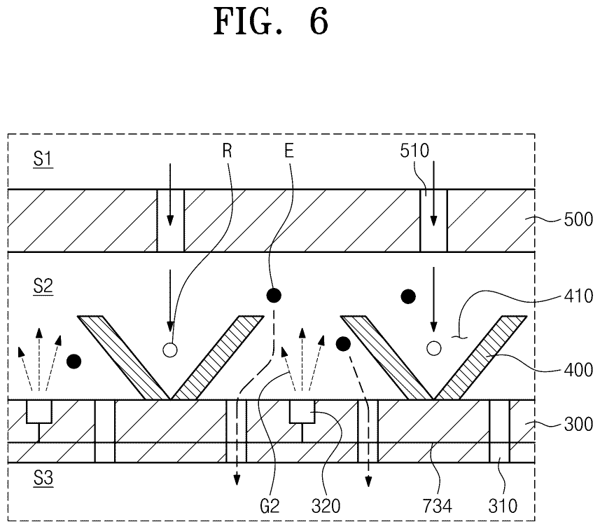

FIG. 5 schematically illustrates a state in which the substrate treating apparatus treats the substrate according to an embodiment. FIG. 6 schematically illustrates an enlarged view of part A of FIG. 5.

Hereinafter, a mechanism by which a substrate is treated in the substrate treating apparatus according to an embodiment will be described in detail with reference to FIG. 5 and FIG. 6.

Various types of thin films exist on the substrate W treated by the substrate treating apparatus 10. For example, the substrate W may include a first film and a second film. For example, the first film may include a silicon oxide film (e.g., SiO2) and/or a silicon nitride film (e.g., SiN). In addition, the second film may include a polysilicon film. However, this is limited for convenience of understanding, and various types of thin films may exist on the substrate W.

The first gas supply unit 710 supplies the first gas G1 to the first space S1. As described above, the first gas G1 is supplied to the first space S1 through the first gas line 714 and the first gas discharge port 610 sequentially.

The first gas G1 supplied to the first space S1 is excited in the plasma P state by the electrode plate 600 to which a high frequency power is applied and the ion blocker 500 which is grounded. The plasma P generated in the first space S1 includes ions and radicals R. For example, the NH₃ gas supplied to the first space S1 may be excited in a plasma state, and the plasma P generated in the first space S1 may include ions and F radicals. Accordingly, the first space S1 functions as a plasma generation space for generating the plasma.

The plasma P generated in the first space S1 is supplied to the second space S2 through the top hole 510 formed in the ion blocker 500. The grounded ion blocker 500 may absorb ions included in the plasma P passing through the top hole 510 and ions in the radical R. Accordingly, only the radical R among the components included in the plasma P may pass through the ion blocker 500 and be supplied to the second space S2. That is, the F radical is supplied to the second space S2. Accordingly, the ion blocker 500 performs a block function of preventing a passage of ions.

As described above, since the top hole 510 is positioned to face the turbulence space 410, the radical R passing through the top hole 510 proceeds to the turbulence space 410. The radical R supplied to the turbulence space 410 collides with an inner wall of the turbulence generating unit 400. Accordingly, a turbulence occurs in a flow of a fluid including the radical R in the turbulence space 410, and a time of which the radical R resides in the second space S2 increases.

The second gas supply unit 730 supplies the second gas G2 to the second space S2. As described above, the second gas G2 is supplied to the second space S2 through the second gas line 734 and the second gas discharge port 320 sequentially. As described above, since the second gas discharge port 320 is disposed to face the bottom surface of the ion blocker 500, the second gas G2 supplied from the second gas discharge port 320 collides with the bottom surface of the ion blocker 500. Accordingly, a turbulence is generated in a flow of the second gas G2 near the bottom surface of the ion blocker 500, and a time of which the second gas G2 resides in the second space S2 increases.

The second gas G2 residing in the second space S2 reacts with the radical R residing in the second space S2 to form an etchant. That is, by increasing a residing time of the second gas G2 and the radical R in the second space S2, the residing time of the radical R and the second gas G2 in the second space S2 can be increased. According to an embodiment, an NF₃, which is the second gas G2, and an F radical react to form an etchant such as an NH₄F (ammonium fluoride), an NH₄F (ammonium hydrogen fluoride), an HF (hydrogen fluoride), etc. Accordingly, the second space S2 functions as a mixing space in which the second gas G2 reacts with the radical R.

The etchant E formed in the second space S2 is supplied to the third space S3 through the bottom hole 310 formed in the shower head 300. As described above, the bottom hole 310 is positioned outside the turbulence space 410. In addition, the bottom hole 310 is positioned to face the outer wall of the turbulence generating unit 400 when viewed from below. Accordingly, it is difficult for the radical R and the second gas G2 residing in the second space S2 to flow out to the third space S3 through the bottom hole 310. That is, according to an embodiment, a reaction time of the radical R and the second gas G2 in the second space S2 may be further increased due to a structure and an arrangement of the bottom hole 310.

The etchant E supplied to the third space S3 may etch the first film of the first film and the second film formed on the substrate W. In addition, very few of the radicals R supplied to the second space S2 may be supplied to the third space S3 through the bottom hole 310 without reacting with the second gas G2. The radical R supplied to the third space S3 may etch the second film of the first film and the second film formed on the substrate W.

That is, according to an embodiment of the inventive concept, an amount of the etchant E formed in the second space S2 may be increased by increasing a residing time of the radical R and the second gas G2 in the second space S2. Accordingly, the amount of the etchant E supplied to the third space S3 is increased, thereby dramatically increasing a selection ratio of the silicon oxide film and the silicon nitride film among the silicon oxide film, the silicon nitride film, and the polysilicon film formed on the substrate W. Conversely, by increasing the residing time of the radical R and the second gas G2 in the second space S2, the amount of the radical R supplied to the third space S3 can be relatively reduced. Accordingly, it is possible to minimize an etching of a polysilicon film formed on the substrate W by the radical R.

In addition, according to the above-described embodiment, a contact surface area between the radical R and the second gas G2 may increase due to the turbulence generated by a collision of the radical R with the turbulence generating unit 400 and a turbulence generated by a collision of the second gas G2 with the bottom surface of the ion blocker 500. Accordingly, a reactivity between the radical R and the second gas G2 is increased, thereby increasing the amount of etchant E generated.

Hereinafter, a substrate treating apparatus according to another embodiment of the inventive concept will be described. The substrate treatment apparatus described below has mostly a same or a similar structure as the substrate treating apparatus 10 described with reference to FIG. 1 to FIG. 6. Accordingly, except for a case of further descriptions, a description of the overlapping content will be omitted.

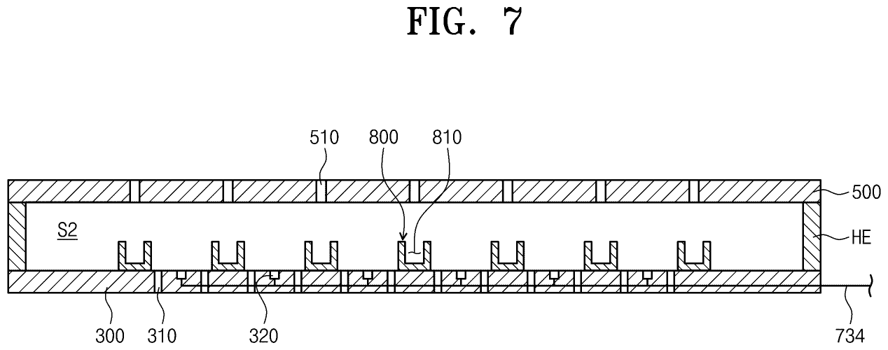

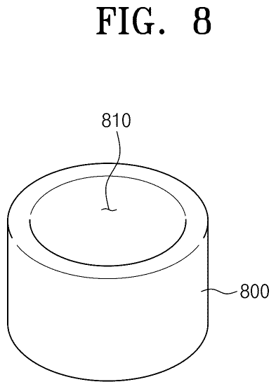

FIG. 7 is a cross-sectional view schematically illustrating the turbulence generating unit according to another embodiment. FIG. 8 is a perspective view of the turbulence generating unit according to another embodiment of FIG. 7.

Referring to FIG. 7 and FIG. 8, the turbulence generating unit 800 may have a substantially cylindrical shape. More specifically, the turbulence generating unit 800 may have a cylindrical shape with an open top portion. The turbulence generating unit 800 has a turbulence space 810 therein.

When seen from above, the turbulence space 810 may overlap the top hole 510. In addition, the bottom hole 310 and the second gas discharge port 320 may be positioned outside the turbulence generating unit 800. That is, when viewed from below, the turbulence space 810 may not overlap the bottom hole 310 and the second gas discharge port 320. Accordingly, an entire region of the bottom hole 310 may face the bottom surface of the ion blocker 500.

A radical supplied from the top hole 510 collides with an inner wall of the turbulence generating unit 800. The second gas supplied from the second gas discharge port 320 to the second space S2 collides with the bottom surface of the ion blocker 500. A mechanism by which the radical supplied to the second space S2 and the second gas react in the second space S2 is the same as or similar to the above-described embodiment, and thus a description thereof will be omitted.

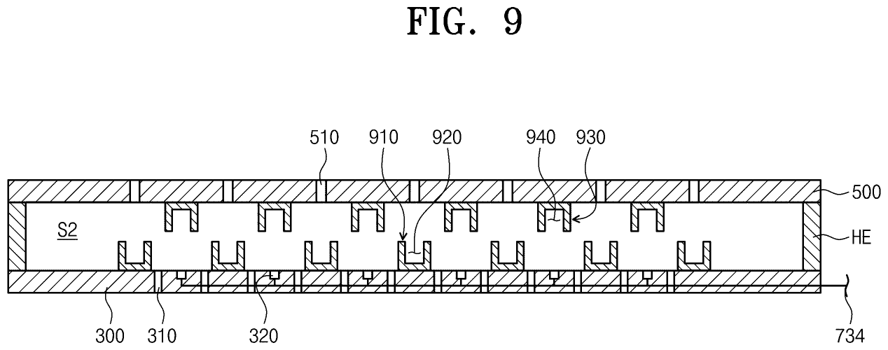

FIG. 9 is a cross-sectional view schematically illustrating the turbulence generating unit according to another embodiment.

Referring to FIG. 9, the turbulence generating units 910 and 930 according to an embodiment may include a first turbulence generating unit 910 and a second turbulence generating unit 930.

The first turbulence generating unit 910 is formed on a top end of the shower head 300. The first turbulence generating unit 910 may have a cylindrical shape with an open top portion. A top end of the first turbulence generating unit 910 is disposed to be spaced apart from a bottom end of the ion blocker 500. The first turbulence generating unit 910 has a first turbulence space 920 therein. The first turbulence space 920 may overlap the top hole 510 when seen from above. In addition, the bottom hole 310 and the second gas discharge port 320 may be positioned outside the first turbulence generating unit 910. That is, when seen from above, the first turbulence space 920 may not overlap the bottom hole 310 and the second gas discharge port 320.

The second turbulence generating unit 930 is formed at a bottom end of the ion blocker 500. The second turbulence generating unit 930 may have a cylindrical shape with an open bottom portion. A bottom end of the second turbulence generating unit 930 is disposed to be spaced apart from a top end of the shower head 300. In addition, the bottom end of the second turbulence generating unit 930 is positioned closer to the ion blocker 500 than the top end of the first turbulence generating unit 910. The second turbulence generating unit 930 has a second turbulence space 940 therein. The second turbulence space 940 may overlap the second gas discharge port 320 when viewed from below. In addition, the second turbulence space 940 may overlap the bottom hole 310 when viewed from below. However, the inventive concept is not limited thereto, and only a partial region of the bottom hole 310 may overlap the second turbulence space 940. Selectively, the bottom hole 310 may be formed at a position deviating from the second turbulence space 940. In addition, the top hole 510 may be positioned outside the second turbulence generating unit 930. That is, when viewed from below, the second turbulence space 940 may not overlap the top hole 510.

According to the above-described embodiment, a radical passing through the top hole 510 may collide with the first turbulence generating unit 910 to generate a turbulence. In addition, the second gas supplied from the second gas discharge port 320 may collide with the second turbulence generating unit 930 to generate a turbulence. A reaction time increases between the radical and the second gas, for which a residing time within the second space S2 increases due to a generated turbulence. Accordingly, an amount of etchant formed in the second space S2 may be increased.

Unlike the above-described example, the first turbulence generating unit 910 may have a first turbulence space 920 therein, but may have a cone shape in which a diameter decreases from a top end to a bottom end thereof. In addition, the second turbulence generating unit 930 may have a second turbulence space 940 therein, but may have a cone shape in which a diameter increases from a top end to a bottom end thereof.

In addition to the above-described embodiments, a shape of the turbulence generating unit may be variously modified. For example, the turbulence generating unit may be transformed into various shapes capable of generating a turbulence in an inner turbulence space.

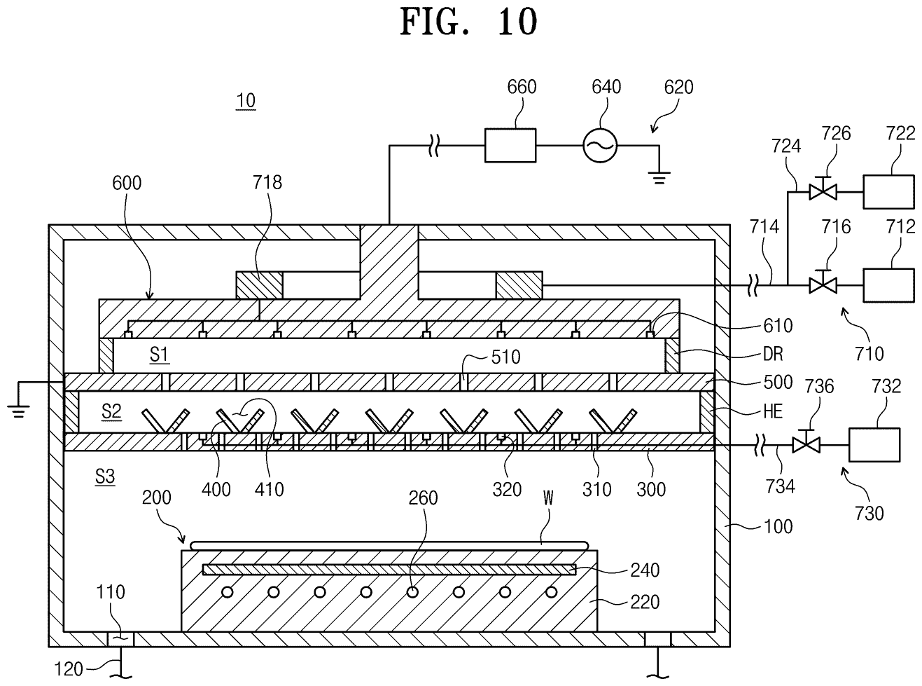

FIG. 10 is a cross-sectional view schematically illustrating the substrate treating apparatus according to another embodiment.

Referring to FIG. 10, the first gas supply unit 710 may further include a pre gas source 722, a pre gas line 724, and a pre valve 726.

The pre gas source 722 stores the pre gas. The pre gas according to an embodiment may be a gas which contributes to removing radicals from ions and radicals included in a plasma. For example, the pre gas may include an H₂. An end of the pre gas line 724 is connected to the pre gas source 722 and the other end thereof is connected to the first gas line 714. A pre-valve 726 is installed in the pre-gas line 724. The pre-valve 726 may be an on-off valve and/or a flow control valve. Accordingly, the pre gas is supplied to the first space S1 sequentially passing through the pre gas line 724, the first gas line 714, and the first gas discharge port 610.

The pre gas supplied to the first space S1 may preemptively remove radicals contained in the plasma generated in the first space S1. For example, the H₂ gas supplied to the first space S1 is decomposed into H radicals by an electric field formed in the first space S1. The H radical reacts with the F radical decomposed from the second gas to form a product such as an HF. Accordingly, an amount of F radicals generated in the first space S1 may be controlled by the pre gas. The amount of F radicals supplied from the first space S1 to the second space S2, the amount of the etchant formed by reacting with the second gas in the second space S2, and the amount of F radicals supplied to the third space S3 can be adjusted by the pre gas supplied to the first space S1.

In accordance with the aforementioned embodiment, the amount of the etchant formed in the second space S2 can be efficiently adjusted by preemptively adjusting the amount of the radical in the first space S1. By adjusting the amount of the etchant, an etching ratio with respect to the first film (e.g., a silicon oxide film and/or a silicon nitride film) formed on the substrate W can be efficiently adjusted.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
an electrode plate applied with a power;
an ion blocker positioned at a bottom side of the electrode plate, which has a plurality of top holes formed thereon, and which is grounded;
a shower head positioned at a bottom side of the ion blocker and which has a plurality of bottom holes formed thereon; and
a turbulence generating unit configured to have a turbulence space therein, and which is positioned at a space between the ion blocker and the shower head, and
wherein the top hole is positioned to overlap the turbulence space when seen from above, and
the bottom hole is positioned at an outer side of the turbulence space, and which faces at least one of a bottom surface of the ion blocker and an outer wall of the turbulence generating unit when seen from below.

2. The substrate treating apparatus of claim 1, wherein the turbulence generating unit is configured to be formed at a top end of the shower head and which has an open top portion, and
a top end of the turbulence generating unit is positioned apart from a bottom end of the ion blocker.

3. The substrate treating apparatus of claim 2, wherein the turbulence generating unit has a shape of which a diameter decreases in a direction toward the shower head.

4. The substrate treating apparatus of claim 2, wherein the turbulence generating unit has a cylinder shape.

5. The substrate treating apparatus of claim 1, wherein the top hole and the bottom hole are positioned to not overlap each other when seen from above.

6. The substrate treating apparatus of claim 1, wherein the turbulence generating unit includes:
a first turbulence generating unit formed at a top end of the shower head and which is configured to have a first turbulence space therein, and which has an open top portion; and
a second turbulence generating unit formed at a bottom end of the ion blocker and which is configured to have a second turbulence space therein, and which has an open bottom portion, and
wherein the top hole is positioned to overlap the first turbulence space when seen from above, and
the bottom hole is positioned to overlap the second turbulence space when seen from above.

7. A substrate treating apparatus having a first space, a second space which is below the first space, and a third space which is below the second space and which treats a substrate, the substrate treating apparatus comprising:
a first gas line which supplies a first gas to the first space;
a second gas line which supplies a second gas to the second space;
a first plate and a second plate which couple to define the second space; and
a turbulence generating unit configured to have a turbulence space therein, and which is positioned in the second space and which generates a turbulence in the turbulence space and second space, and
wherein a plurality of first holes are formed at the first plate which communicate with the first space and the second space, and
the first hole is positioned to overlap with the turbulence space when seen from above.

8. The substrate treating apparatus of claim 7, wherein the first plate is positioned above the second plate, and
wherein the turbulence generating unit has an open top portion, and which is formed at a top end of the second plate.

9. The substrate treating apparatus of claim 8, wherein the second plate has a plurality of second holes which communicate with the second space and the third space, and
wherein the plurality of second holes are positioned at an outside of the turbulence space.

10. The substrate treating apparatus of claim 9, wherein a plurality of second gas discharge ports connected to the second gas line are formed at a top portion of the second plate, and
the second gas discharge ports are positioned at the outside of the turbulence space.

11. The substrate treating apparatus of claim 10, wherein the first hole, the second hole, and the second gas discharge port are disposed to not overlap each other when seen from above.

12. The substrate treating apparatus of claim 9, wherein a top end of the turbulence generating unit is spaced apart from the bottom end of the first plate.

13. The substrate treating apparatus of claim 12, wherein the turbulence generating unit has a shape of which a diameter decreases from the top end to a bottom end, and
the plurality of second holes overlap with at least a portion of an outer wall of the turbulence generating unit when seen from below.

14. The substrate treating apparatus of claim 12, wherein the turbulence generating unit has a cylinder shape, and the plurality of second holes face the bottom surface of the first plate when seen from below.

15. The substrate treating apparatus of claim 7, further comprising:
an electrode plate which is spaced apart from the first plate and positioned at a top side of the first plate, and
wherein the electrode plate is applied with a high frequency power, and
the first plate is grounded.

16. The substrate treating apparatus of claim 15, wherein a plurality of first gas discharge ports connected to the first gas line are formed at a bottom portion of the first plate, and the plurality of first gas discharge ports are positioned to not overlap each of the plurality of first holes when seen from above.

17. The substrate treating apparatus of claim 16, wherein the first space generates a plasma by exciting the first gas, and
the second gas forms an etchant by reacting a radical among a material including the plasma and the second gas.

18. The substrate treating apparatus of claim 17, wherein the first gas includes an NF₃, and the second gas includes an NH₃.

19. The substrate treating apparatus of claim 18, further comprising a pre gas line supplying a pre-gas to the first space, and
wherein the pre-gas reacts with the radical in the first space.

20. A substrate treating apparatus comprising:
an electrode plate applied with a high frequency power;
an ion blocker positioned at a bottom side of the electrode plate and spaced apart from the electrode plate, which has a plurality of top holes formed thereon, and which is grounded;
a shower head positioned at a bottom side of the ion blocker and spaced apart from the ion blocker, and which has a plurality of bottom holes formed thereon; and
a turbulence generating unit configured to have a turbulence space therein, and which is positioned at a top end of the shower head;
a support unit configured to support a substrate at a bottom side of the shower head;
a first gas supply unit configured to supply a first gas to a space between the electrode plate and the ion blocker; and
a second gas supply unit configured to supply a second gas to a space between the ion blocker and the shower head, and
wherein a top end of the turbulence generating unit is spaced apart from a bottom end of the shower head,
the top hole and the bottom hole are positioned to not overlap each other when seen from above,
the top hole faces the turbulence space when seen from above, and
the bottom hole is positioned at an outside of the turbulence space.
